(19) United States
(12) Patent Application Publication
(10) Pub. No.: US 2025/0283958 A1
(43) Pub. Date: Sep. 11, 2025

(54) METHOD AND APPARATUS FOR HYPERPOLARIZING SUBSTRATE MOLECULES

(71) Applicants: Wayne State University, Detroit, MI (US); North Carolina State University, Raleigh, NC (US)

(72) Inventors: Eduard Y. Chekmenev, Troy, MI (US); Thomas Theis, Raleigh, NC (US); Austin Browning, Raleigh, NC (US); Keilian Macculloch, Raleigh, NC (US); Patrick TomHon, Raleigh, NC (US); Shiraz Nantogma, Detroit, MI (US)

(21) Appl. No.: 18/858,937

(22) PCT Filed: Apr. 21, 2023
(86) PCT No.: PCT/US2023/019404

§ 371 Date: Oct. 22, 2024

Related U.S. Application Data
(60) Provisional application No. 63/334,117, filed on Apr. 23, 2022.

(51) Int. Cl. G01R 33/28

(52) U.S. Cl. CPC G01R 33/282

(57) ABSTRACT

A hyperpolarization system including a solution and at least one magnetic field controller. The solution includes at least parahydrogen, a polarization transfer complex (PTC), and substrate molecules. The at least one magnetic field controller is configured to apply a static ultra-low magnetic field to the solution and apply an alternating ultra-low magnetic field to the solution. Through application of the ultra-low magnetic fields to the solution, the system hyperpolarizes at least some of the substrate molecules.

### CROSS-REFERENCE TO RELATED APPLICATIONS

This application claims priority to U.S. Provisional Application No. 63/334,117 filed on Apr. 23, 2022, the contents of which is hereby incorporated by reference in its entirety.

### GOVERNMENT LICENSE RIGHTS

The invention was made with government support under grant numbers EB025313 and EB029829 awarded by the National Institutes of Health. The government has certain rights in the invention.

### FIELD OF TECHNOLOGY

An improved contrast agent system and method are disclosed. Improvements are applicable to the fields of nuclear magnetic resonance (NMR) technology and magnetic resonance (MR) technology.

### BACKGROUND

Biomedical nuclear magnetic resonance (NMR) hyperpolarization increases nuclear spin polarization above thermal levels by generally 4-6 orders of magnitude, with corresponding gains in the detected signal. Hyperpolarized (HP) magnetic resonance imaging (MRI) has emerged as a promising alternative to positron emission tomography (PET) tracers for real-time metabolic imaging because low-concentration metabolites such as pyruvate can be mapped in vivo. Moreover, detection of ¹³C-hyperpolarized nuclei generally enables imaging without tissue background signal. Unlike PET, HP MRI employs no ionizing radiation. Moreover, HP MRI scans can be completed in, for example, one minute or less. As such, HP MRI offers an unprecedented exam speed. HP [1-¹³C]pyruvate has emerged as a popular HP contrast agent for probing anaerobic glycolysis, which is a central metabolic pathway frequently upregulated in cancers and other metabolically challenged diseases. The pyruvate ¹³C-1 nucleus offers a relatively long HP state lifetime in vivo (e.g., a T1 of ˜1 min) and excellent chemical shift dispersion of downstream metabolites (e.g., [1-¹³C]lactate, ¹³C-bicarbonate, and [1-¹³C]alanine). As such, simultaneous mapping via spectroscopic MRI can be carried out. Accordingly, HP [1-¹³C]pyruvate may revolutionize molecular imaging in the future and emerge as a good alternative to [18F]fluorodeoxyglucose (18F-FDG) tracers widely employed in PET molecular imaging of cancer and other diseases.

HP [1-¹³C]pyruvate is currently produced at clinical scales via dissolution Dynamic Nuclear Polarization (d-DNP) techniques. These techniques generally employ cryogenic temperatures, high magnetic fields, and high-power microwave irradiation. These techniques, however, are generally expensive. For example, a clinical-scale device to carry out these techniques may cost over two million dollars. Further, operation of such devices generally require expensive cryogens. Still further, a 5 T SpinLab device, for example, may need approximately 1 hour to produce a clinical dose of HP [1-¹³C]pyruvate with ¹³C polarization (P¹³C) with a typical failure rate of, for example, 13%. As a result, slow and expensive hyperpolarization production can limit the biomedical translation of ultrafast HP [1-¹³C]pyruvate MRI.

Accordingly, there is a need for a system and method for faster, more robust, and more affordable approaches to accelerate the accessibility of HP [1-¹³C]pyruvate.

### BRIEF DESCRIPTION OF THE DRAWINGS

FIG. 1A illustrates an exemplary schematic of simultaneous chemical exchange of pH₂ and [1-¹³C]pyruvate on activated IrIMes catalyst complexes 3a and 3b to yield “free” HP [1-¹³C]pyruvate;

FIG. 1B illustrates an exemplary ¹³C NMR spectrum of 27 mM HP sodium [1-¹³C]pyruvate prepared via pseudo-alternating microtesla magnetic-field method;

FIG. 1C illustrates a corresponding exemplary ¹³C spectrum of signal reference compound (neat [1-¹³C]acetic acid);

FIG. 1D illustrates an exemplary device for preparing hyperpolarized (HP) [1-¹³C]pyruvate;

FIG. 2 illustrates an exemplary schematic of SABRE pre-catalyst activation to form complexes 2, 3a and 3b;

FIG. 3 illustrate an exemplary schematic of the three-spin system and relevant parameters employed in the numerical simulations;

FIG. 4A is a graph illustrating exemplary demonstration results, where a combination of alternating and static microtesla magnetic fields were employed;

FIG. 4B is another graph illustrating additional exemplary demonstration results, where a combination of alternating and static microtesla magnetic fields were employed;

FIG. 4C is another graph illustrating additional exemplary demonstration results, where a combination of alternating and static microtesla magnetic fields were employed;

FIG. 4D is another graph illustrating additional exemplary demonstration results, where a combination of alternating and static microtesla magnetic fields were employed;

FIG. 5A is an exemplary graph illustrating the dependence of ¹³C-1 polarization of [1-¹³C]pyruvate on the low-field amplitude, B_{LOW}, when the combination of alternating and static microtesla fields were employed;

FIG. 5B is an exemplary graph illustrating the dependence of ¹³C-1 polarization of [1-¹³C]pyruvate on the high-field amplitude, B_{HIGH}, when the combination of alternating and static microtesla fields were employed;

FIG. 5C is an exemplary graph illustrating the dependence of ¹³C-1 polarization of [1-¹³C]pyruvate on the duration of the low field pulse duration, τ_{LOW}, when the combination of alternating and static microtesla fields were employed;

FIG. 5D is an exemplary graph illustrating the dependence of ¹³C-1 polarization of [1-¹³C]pyruvate on the duration of the high field pulse duration, τ_{HIGH}, when the combination of alternating and static microtesla fields were employed;

FIG. 5E is an exemplary graph illustrating the dependence of ¹³C-1 polarization of [1-¹³C]pyruvate on the high-field amplitude, B_{HIGH}, when the combination of alternating and static microtesla fields were employed using sup-optimal sets of experimental parameters compared to that shown in FIG. 5B;

FIG. 5F is an exemplary graph illustrating the dependence of ¹³C-1 polarization of [1-¹³C]pyruvate on the duration of the high field pulse duration, τ_{HIGH}, when the combination of alternating and static microtesla fields were employed using sup-optimal sets of experimental parameters compared to that shown in FIG. 5B;

FIG. 6 is an exemplary graph illustrating exemplary fitting exchange rates from pulsed SABRE-SHEATH τ_{HIGH} Sweeps;

FIG. 7A is an exemplary graph illustrating exemplary ¹³C-1 polarization build-up of [1-¹³C]pyruvate via conventional SABRE-SHEATH (static fields; control experiment) (−0.42 μT static field) and pulsed SABRE-SHEATH (i.e., the application of alternating and static magnetic fields);

FIG. 7B is an exemplary graph illustrating exemplary ¹³C T₁ polarization decay of [1-¹³C]pyruvate at −0.42 μT static field (control experiment) and during application of SABRE-SHEATH pulses (i.e., the application of alternating and static magnetic fields);

FIG. 7C is an exemplary graph illustrating exemplary ¹³C polarization decay of [1-¹³C]pyruvate due to polarization dephasing associated with the shields' residual magnetization in the x-y plane for four representative magnetic fields of interest applied along the shield's z-direction;

FIG. 7D is an exemplary graph illustrating exemplary ¹³C T₁ polarization decay of [1-¹³C]pyruvate at the Earth's field and 1.4 T;

FIG. 7E is an exemplary graph illustrating exemplary simulations of Ta decay due to x-y in-situ field inhomogeneities as a function of the applied magnetic field B_{z};

FIG. 7F is an exemplary graph illustrating exemplary corresponding values of root-mean-square deviation (RMSD) between simulations and experimental results;

FIG. 8A is a block diagram of an exemplary system to hyperpolarize [1-¹³C]pyruvate;

FIG. 8B is a block diagram of an exemplary precursor that that may be employed to make a hyperpolarizing solution;

FIG. 8C illustrates an exemplary vessel that may be employed to carry the precursor of FIG. 8B;

FIG. 9 illustrates an exemplary technique for creating hyperpolarized [1-¹³C]pyruvate; and

FIG. 10 illustrates an exemplary technique to create a precursor that may be used to create the solution of FIG. 9.

### DETAILED DESCRIPTION

Among other things, examples discussed herein relate to nuclei (e.g., ¹³C) Signal Amplification by Reversible Exchange (SABRE) hyperpolarization using the application of a combination of alternating and static ultra-low magnetic fields, where ultra-low magnetic fields are in a range from 0.001 microtesla to 39,999 microtesla. An alternating ultra-low magnetic field is an ultra-low magnetic field that changes direction, rate of flow (frequency), and strength over a time interval.

Generally, SABRE includes mixing parahydrogen (e.g., a polarized H₂ gas) with a catalyst, and a substrate (i.e., a compound to be hyperpolarized). When proper magnetic fields are applied to the mixture, the polarization of the parahydrogen effectively transfers to the catalyst and then to the substrate, thus creating a hyperpolarized substrate. The hyperpolarized substrate may then be used in a wide variety of applications. For example, nuclear magnetic resonance (NMR) and/or magnetic resonance imaging (MRI) leverage the polarization of structures during their operation. As such, hyperpolarized substrates created by SABRE are often employed in MRI and/or NMR applications.

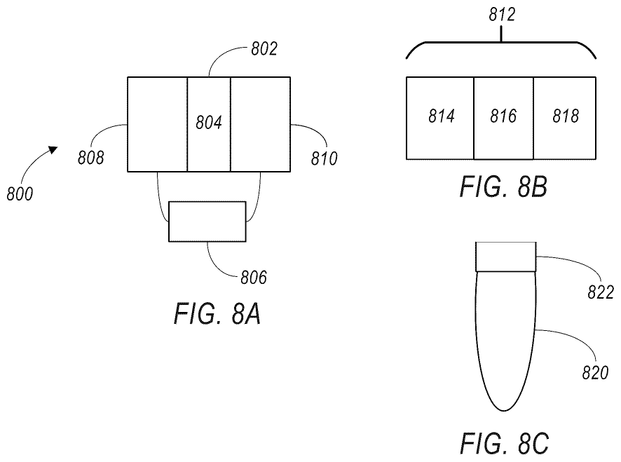

With reference to FIG. 8A, a block diagram of an exemplary hyperpolarization system 800 is shown. The exemplary system 800 includes a container 802 to hold a solution 804, along with at least one magnetic field controller 806—other examples may employ one or more additional magnetic field controllers. The magnetic field controller 806 of FIG. 8A is configured to control a first magnetic field coil 808 and a second magnetic field coil 810. Together, the magnetic field controller 806 and the magnetic field coils 808, 810 may be configured to create magnetic fields in a range from 0.001 microtesla to 39,999 microtesla (a.k.a. ultra-low magnetic fields).

The solution 804 includes at least parahydrogen, a polarization transfer complex (PTC), and substrate molecules. The magnetic field controller 806 is configured to apply a static ultra-low magnetic field (i.e., an ultra-low B₀ field) via the first magnetic field coil 808 and an alternating ultra-low magnetic field via the second magnetic field coil 810 to the solution 804 to cause hyperpolarization of at least some of the substrate molecules in the solution 804. In another example, the first magnetic coil 808 could instead apply the alternating ultra-low magnetic field, while the second magnetic coil 810 provides the static ultra-low magnetic field.

It is unusual that such ultra-low alternating and static magnetic fields cause such hyperpolarization since it was thought that application of alternating magnetic fields at ultra-low static fields would not differentiate between the free and bound states during SABRE process, and therefore, would largely destroy hyperpolarization on the free substrate molecule. Conventional wisdom appeared to show that irradiating free species should be avoided by employing larger magnetic fields so that only molecules bound to a catalyst (i.e., bound species) are affected. Conventionally, the application of alternating fields at ultra-low static magnetic fields were avoided since, at these fields, the frequencies of the bound and the free species in SABRE cannot be readily discriminated. As such, it was thought that irradiating the free species with alternating fields of similar frequencies (i.e., ultra-low magnetic fields) would excite the free species in such manner as to destroy hyperpolarization of the free species of the substrate molecules rendering polarization build-up during SABRE process highly inefficient. In contrast however, examples described herein show that ultra-low static and alternating magnetic fields can be applied to the solution 104 to cause hyperpolarization of substrate molecules.

The substrate molecules may include, for example [1-¹³C]pyruvate molecules and dimethyl sulfoxide (DSMO) molecules, where at least some of the [1-¹³C]pyruvate molecules become hyperpolarized as the static and alternating magnetic fields are applied. It is noted that nuclei besides ¹³C may instead be employed. That is, instead of hyperpolarizing the nuclei of [1-¹³C]pyruvate molecules, other molecules may instead be hyperpolarized via the static and alternating ultra-low magnetic fields.

The magnetic field controller 806 may be configured to apply the static ultra-low magnetic field (i.e., an ultra-low B₀ field) via the first magnetic field coil 808 and the alternating ultra-low magnetic field (i.e., an ultra-low B₁ field) via the second magnetic field coil 810 at substantially the same time. For example, the ultra-low B₀ field may be applied, and then an alternating ultra-low B₁ magnetic field may be applied for a short period of time via a B₁ pulse as the ultra-low B₀ field is applied. Alternatively, the magnetic field controller 806 may be configured to apply the static ultra-low magnetic field via the first magnetic field coil 808 before applying the alternating ultra-low B₁ magnetic field via the second magnetic coil, or vice versa. For example, an ultra-low B₀ field may be applied and then reduced or increased before the alternating ultra-low B₁ magnetic field is applied. Still further, the magnetic field controller 806 may be configured to cause variable static and/or alternating ultra-low magnetic fields to be applied to the solution 804 via the first and second magnetic field coils 808, 810.

It is noted that the system 800 may be configured to apply the static magnetic field either parallel or orthogonal to the alternating magnetic field. Further, either the static magnetic field and/or the alternating agentic field applied by the respective magnetic field coils 808, 810 may include from one to three spatial directions or components.

While the exemplary system 800 of FIG. 8A includes two magnetic field coils 808, 810, other exemplary system may include more than two magnetic field coils. Further, other exemplary systems may include only one magnetic field coil. In such an exemplary system, one magnetic field coil would apply both the static ultra-low magnetic field and the alternating ultra-low magnetic field. As such, in such a system that employed only one magnetic field coil, the static ultra-low magnetic field would be applied before the alternating ultra-low magnetic field is applied.

With reference now to FIG. 8B, a block diagram of a precursor components 812 to create the solution 804 of FIG. 8A is shown. The precursor components 812 of FIG. 8B include a nuclei source 814 (e.g., [1-¹³C]pyruvate molecules) (a.k.a., substrate molecules), DSMO 816 (additional substrate molecules), and a pre-catalyst 818 (e.g., (IrCl(COD)(IMes)). The precursor 812 may be mixed in a vessel 820 (FIG. 8B), which may be purged with, for example, argon gas to ensure a high purity of the precursor 812 and capped 822 for later use. The precursor 812 may be created at a remote facility and then shipped to an institution carrying out NMR and/or MRI activities. Once received by the institution, and prior to carrying out the NMR and/or MRI activities, the precursor 812 may be activated by the adding parahydrogen thereto, thus creating the solution 804 of FIG. 8A. The addition of the parahydrogen to the precursor 812 effectively knocks the COD cap off of the pre-catalyst 818, thus changing it to the PTC of the solution 804.

The parahydrogen may be added to the precursor 812 in a variety of ways to create the solution 804. For example, the precursor 812 may be placed in a magnetic shield of a polarizer and then parahydrogen gas may be bubbled through the solution for a period of time (e.g., twenty minutes) to create the solution 804. As discussed above with respect to FIG. 8A, static and alternating ultra-low magnetic fields are applied to the solution 804 to create hyperpolarized material.

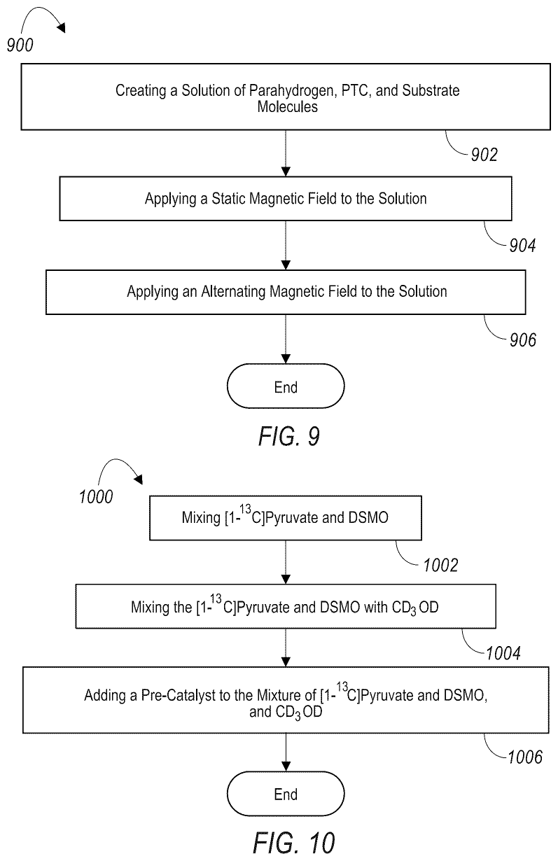

Referring now to FIG. 9, an exemplary technique 900 for hyperpolarizing a substrate is shown. The method includes creating a solution including parahydrogen, a polarization transfer complex (PTC), and substrate molecules at block 902. Next, the exemplary technique 900 includes applying a static ultra-low magnetic field to the solution at block 904 and applying an alternating ultra-low magnetic field to the solution at block 906. The static and the alternating ultra-low magnetic fields may be in a range from 0.001 microtesla to 39,999 microtesla. The application of the static and alternating ultra-low magnetic fields induces hyperpolarization of at least some of the substrate molecules. For example, if the substrate molecules include [1-¹³C]pyruvate molecules and dimethyl sulfoxide (DSMO) molecules, the application of the static and alternating ultra-low magnetic fields hyperpolarizes [1-¹³C]pyruvate molecules.

While the exemplary technique 900 of FIG. 9 illustrates that the static ultra-low magnetic field 904 is applied before the alternating ultra-low magnetic field 906, other exemplary techniques may apply the static ultra-low magnetic field at substantially the same time the alternating ultra-low magnetic field is applied. For example, the ultra-low B₀ field may be applied for a time interval. Then, at some time during this time interval, the solution may be pulsed by an alternating ultra-low B₁ magnetic field.

In some examples, the amplitudes and phases of static and/or alternating ultra-low magnetic fields are variable, and in others they are not. Further, in some examples, the alternating ultra-low magnetic field may be applied in a direction parallel to the static ultra-low magnetic field, while in other examples the alternating ultra-low magnetic field may be applied in an orthogonal direction to the static ultra-low magnetic field.

It is noted that, the creation of the solution at block 902 may include creating the PTC via a pre-catalyst, where interaction of the parahydrogen with the pre-catalyst creates the PTC. For example, the pre-catalyst may include (IrCl(COD)(IMes). When adding parahydrogen (e.g., via bubbling) to the (IrCl(COD)(IMes), the PTC may be formed.

With reference now to FIG. 10, an exemplary technique 1000 for creating a hyperpolarizing precursor is shown. The exemplary technique 1000 includes mixing a nuclei source (e.g., 30 mM of [1-¹³C]pyruvate) and, for example, DSMO (e.g., 20 mM or 40 mM) at block 1002. The nuclei source and the exemplary DSMO can be considered substrate molecules.

Process control then proceeds to block 1004, where mixing the substrate molecules (e.g., [1-¹³C]pyruvate and DSMO) with, for example, CD₃OD (e.g., 2.0 mL) occurs. At block 1006, adding a pre-catalyst (e.g., (IrCl(COD)(IMes)) to the mixture (e.g., the mixture of [1-¹³C]pyruvate, DSMO, and CD₃OD) is carried out to effectively create a hyperpolarizing precursor (see, e.g., the precursor 812 of FIG. 8B). In some instances, process control then comes to an end.

While discussions above (e.g., the FIG. 10 discussion) use [1-¹³C]pyruvate as an exemplary nuclei source, other molecules could instead be used as a nuclei source. For example, molecules with ¹³C, ¹⁵N, ¹H, and/or other NMR active metal nuclei (to name a few) may be employed as a nuclei source.

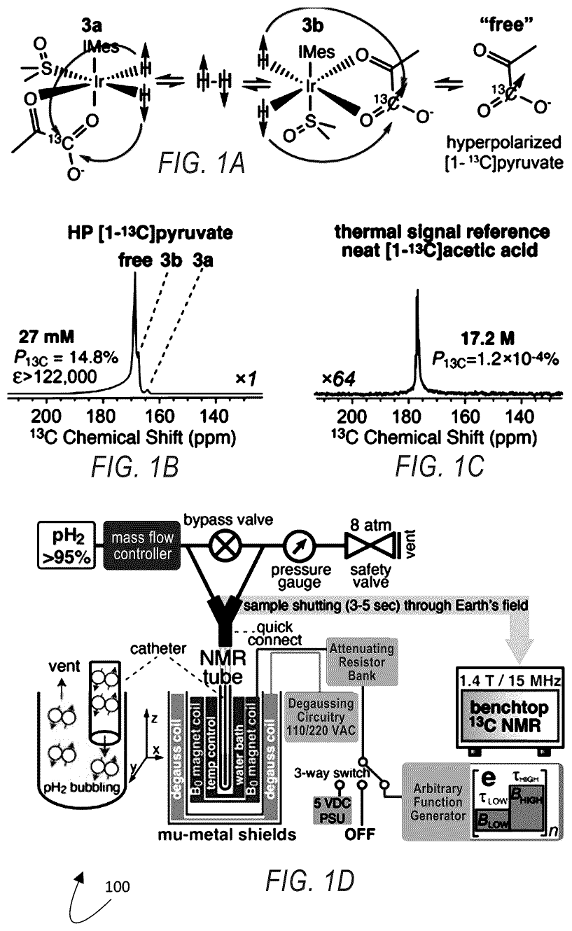

The discussion below, along with FIGS. 1-7, describe exemplary experimental setups and validations related to the hyperpolarization of a nuclei source via the application of static and alternating ultra-low magnetic fields. As with discussions above, the [1-¹³C]pyruvate discussed below is merely exemplary. That is, another nuclei source (e.g., [¹⁵N₃]metronidazole molecules) could instead be employed to enable hyperpolarization thereof via application of static and alternating ultra-low magnetic fields.

In one example, samples were prepared by creating a stock solution of 30 mM of [1-¹³C]pyruvate mixed with 20 mM or 40 mM of DMSO (dried over molecular sieves) in 2.0 mL of CD₃OD. 600 μL of this stock solution was measured into a 1.5 mL Eppendorf tube containing 2.3 mg of SABRE pre-catalyst (IrCl(COD)(IMes), 1), and 60 μL of 10% HPLC-grade water in CD₃OD. This procedure resulted in a pre-catalyst concentration of 6 mM, a [1-¹³C]pyruvate concentration of 27 mM, a DMSO concentration of 18 mM or 36 mM, and an H₂O concentration of 0.5 M. Each sample was transferred into a medium-wall NMR tube and purged with ultra-high purity Argon gas for 2 minutes and capped. The samples were then taken to a polarizer setup for activation. All experiments were performed using a cold-water bath with temperature of 10° C.

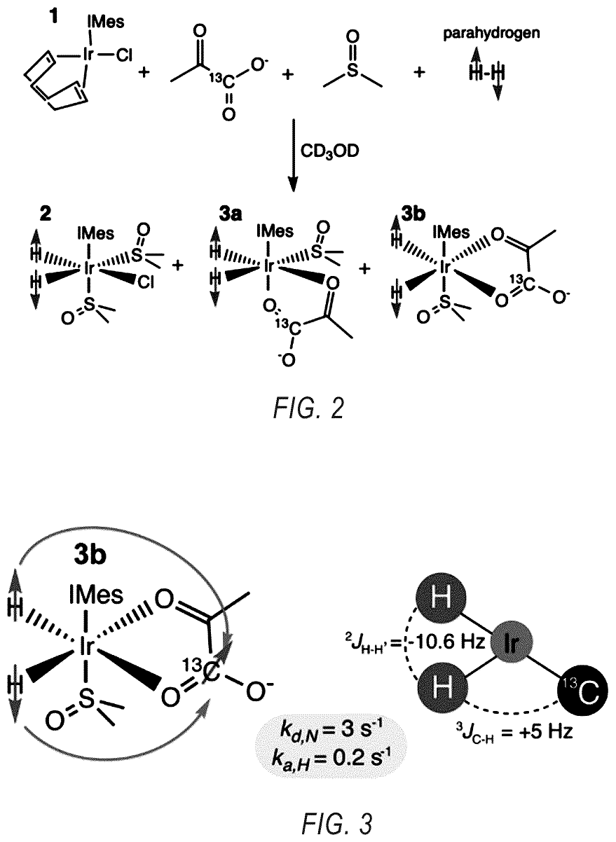

Each sample was activated by bubbling parahydrogen (p-H₂) gas (e.g., a gas in a >98% para-state) through the sample for 20 minutes inside a magnetic shield of the polarizer. Other activation steps, however, could instead be employed. Nonetheless, this activation step discussed above was performed after purging the gas manifold of the hyperpolarizer with p-H₂ gas for at least 5 minutes to remove any trapped oxygen-containing air. The pre-catalyst activation leads to formation of complexes (e.g., see complexes 1, 3a and 3b as described in FIG. 2). Complex 3b is SABRE active, i.e., leading to formation of free HP [1-¹³C]pyruvate (see reaction of FIG. 1A).

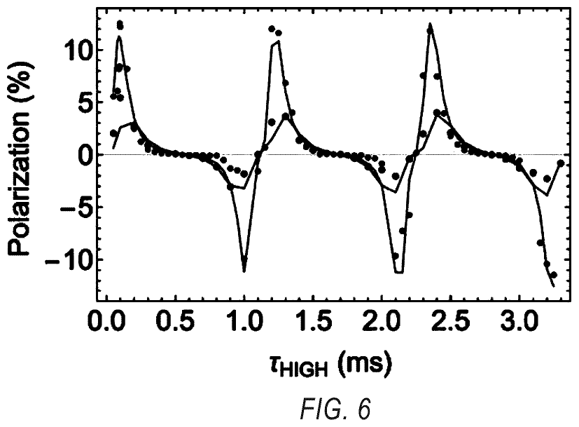

In one example, an integrated setup including a two-layered mu-metal shield was used to attenuate the Earth's magnetic field to less than 40 nT residual field. The field inside the shield was created via a compensated solenoid coil using either a DC power supply (for conventional SABRE-SHEATH, at fixed field of −0.42 μT with 90% homogeneity over its 7″ length) or via the output signal of an arbitrary function generator. The field was monitored by a 3-axis fluxgate magnetometer. The activated sample (in a 5 mm NMR tube) was bubbled with p-H₂ (˜8 atm total pressure (unless otherwise noted) and 70 standard cubic centimeters per minute (sccm) unless noted otherwise) at an optimized temperature of 10° C. (see FIG. 6), either using the static −0.42 μT field or microtesla pulses as shown in FIG. 1D. After SABRE hyperpolarization was completed, the p-H₂ bubbling was ceased, and the sample was manually shuttled to a 1.4 T bench-top NMR spectrometer: either a SpinSolve Carbon 60 or an NMR Pro60. The delay between p-H₂ flow cessation and acquisition of an enhanced ¹³C NMR spectrum (without proton decoupling) was approximately 3-5 seconds. The sample was placed at the center of the shield with a static magnetic field of −0.42 μT. The static magnetic field was created by an electromagnet placed in the degaussed mu-metal shield. The DC current was attenuated via a resistor bank to achieve the desired field and the field was verified by a fluxgate magnetometer. Note the field inside the shield is negative with respect to the detecting 1.4 T magnet and bubbled with p-H₂ for ˜30 s at a flow rate of 70 sccm and total p-H₂ pressure of 8 bar (unless noted otherwise). The sample was then quickly transferred into a 1.4 T benchtop NMR spectrometer for detection.

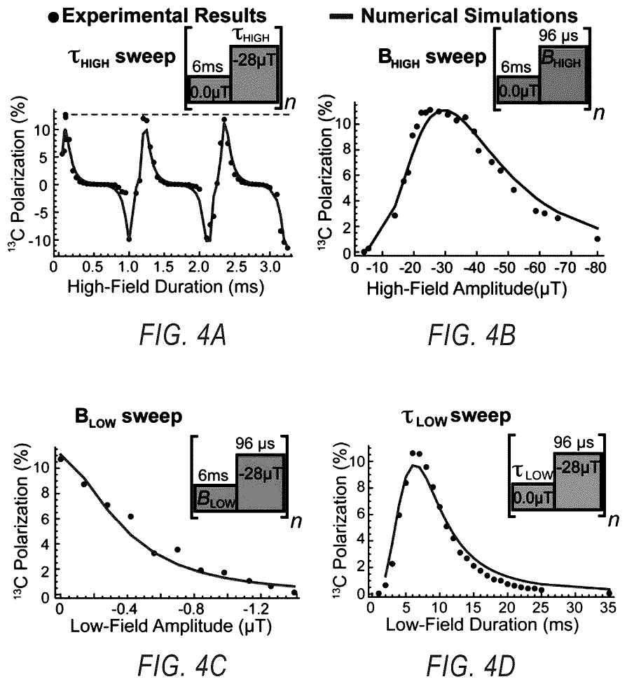

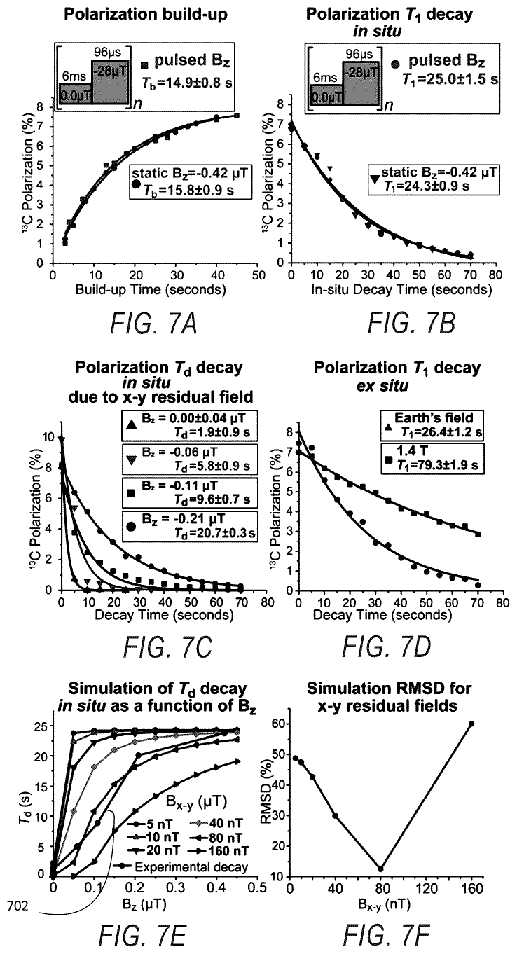

In one example, pulse sequence parameters were set on an arbitrary function generator by creating a square pulse with an amplitude of 2.5 V and zero-offset of −14 to −18 mV (to ensure that the field is set to less than 40 nT (the detection limit of magnetometer)), a period of 4 s, and a duty cycle of 2 s. The use of arbitrary function generator allowed for delivering the combination of alternating and static microtesla magnetic fields and also for delivering pure static magnetic field (control experiment). In case of the use of pulses of the sequence employing alternating fields, the pulse rise and duration were verified via oscilloscope. This approach allows the measurement of the low field and high field amplitudes using a fluxgate magnetometer and to adjust the current (and by extension the magnetic field of the coil) using a resistor bank before proceeding with the actual pulse (note that setting the field strength parameters of the sequence with high-frequency oscillations would render an average value detected by the magnetometer, which is not wanted). Once the high and low field amplitudes were confirmed, the low field and high field durations were set on the waveform generator and turned off. Hyperpolarization experiments were then started by turning on the waveform generator (a.k.a., a magnetic field controller) and p-H₂ bubbling valve at the same time. The p-H₂ bubbling was stopped after 30 s and allowed to settle for a second before the sample was transferred to the NMR spectrometer for detection as detailed above. Examples of SABRE run employing the combination of alternating and static microtesla magnetic fields are shown in FIGS. 4A-4D. The [1-¹³C] polarization build-up curves (e.g., FIG. 7A) were obtained by varying the duration of p-H₂ bubbling of the sample placed inside the shield—one data point was obtained from each experiment with variable duration of p-H₂ bubbling. All other experimental parameters were kept the same. In case of ¹³C polarization in-shield T1 decay measurements at −0.42 μT, the ¹³C polarization was allowed to build for 30 seconds during p-H₂ bubbling. Next, the p-H₂ flow was stopped by opening a bypass valve, FIG. 1D. Next, the sample was allowed to stay in the shield for ¹³C polarization decay for a given period prior to rapid transfer to high field (1.4 T) for detection, e.g., FIG. 7B. Thus, the data was collected by acquiring one data point per each experiment. All other experimental parameters were kept the same. All data points before t=6 s were excluded (from the data fitting) to eliminate any contribution from residual polarization build-up inside the shield due to residual p-H₂.

In one example, ¹³C polarization T1 decay measurements were also performed under conditions of applying the combination of alternating and static microtesla magnetic fields. These studies were performed by bubbling p-H₂ in the shield for 30 seconds, while the pulse was running and then varying the time the sample spent in the shield after cessation of p-H₂ bubbling before detection-one data point was obtained from each experiment. All other experimental parameters were kept the same. All data points before t=6 s (from the data fitting) were excluded to eliminate any contribution from polarization build-up inside the shield due to residual p-H₂.

¹³C NMR data acquisition for ¹³C polarization T1 decay in the Earth's field (ca. 50 μT) was performed as a control experiment. These studies were performed by p-H₂ bubbling in the shield for 30 s and then quickly shuttling the sample out of the shield and into the Earth's field, and then varying the time the sample has spent in the Earth's field before detection at 1.4 T. One data point was obtained from each experiment. All other experimental parameters were kept the same. All data points before t=6 s were excluded to eliminate any contribution from polarization build-up due to residual p-H₂.

¹³C NMR data acquisition for ¹³C polarization T1 decay in 1.4 T field was performed as the additional control experiment. The studies were performed by p-H₂ bubbling in the shield for 30 s. The p-H₂ flow was stopped, and the sample was transferred to the 1.4 T NMR spectrometer. Then, the duration of time that the HP sample spent in the spectrometer before NMR detection was varied-one data point was obtained from each experiment. All other experimental parameters were kept the same. All data points before t=6 s (from the data fitting) were excluded to eliminate any contribution from polarization build-up due to residual p-H₂.

In one example, computation of ¹³C polarization enhancement and polarization values were performed as follows. ¹³C NMR signals from [1-¹³C]pyruvate (concentration, C_{HP}=0.027 M) were recorded using single-scan acquisitions using a 1.4 T benchtop NMR spectrometer as described above. The HP spectra was recorded from samples placed in medium-wall NMR tubes with a 1/16″ outer diameter (OD) Teflon catheter placed inside. The obtained HP signal (S_{HP}) was compared to a thermally polarized signal reference sample (neat [1-¹³ C]acetic acid, C_{REF}=17.5 M, FIG. 1C) placed inside a regular-wall NMR tube. ¹³C signal enhancements (ε_{13C}) were computed using Eq. 1.

$${ε}_{13 C} = \frac{{S}_{HP}}{{S}_{REF}} \times \frac{{C}_{REF}}{{C}_{HP}} \times \frac{{A}_{REF}}{{A}_{HP}} = \frac{{S}_{HP}}{{S}_{REF}} \times \frac{{C}_{REF}}{{C}_{HP}} \times 1.705 , \qquad ( Eq . 1 )$$

where A_{REF} and AHP are effective cross-sections of reference and HP samples in regular wall and medium-wall NMR tubes, respectively. The ratio (A_{REF}/A_{HP}) was determined experimentally for both NMR spectrometers employed and was found to be 1.705, and was used in Eq. 1. The P_{13C} value was computed according to Eq. 2:

$${P}_{13 C} = {ε}_{13 C} \times {P}_{therm} , \qquad ( Eq . 2 )$$

where Ptherm (1.20×10⁻⁴%) is the ¹³C thermal polarization level at 1.4 T and 298 K.

An example of ¹³C signal enhancement and polarization calculations for the spectrum shown in FIG. 1B is provided below:

$${ε}_{13 C} = \frac{10849}{97.77} \times \frac{17.5}{0.0270} \times 1.705 = 1.22 \times 1 {0}^{5} ; and$$

$${P}_{13 C} = 1.22 \times 1 {0}^{5} \times 1.20 \times 1 {0}^{- 4} \% = 14.8 \% .$$

In one example, numerical simulations were run using a physically accurate numerical simulation method. The modelled spin system was simplified extensively (see FIG. 3) because many of the exchange and coupling parameters are as yet unknown. The imposed simplifications are as follows: (1) the methyl protons are truncated out of both the free and bound spin systems; (2) only the polarization transfer complex 3b is simulated here; (3) the J coupling network has not been fully determined for this configuration, so the parameters used were not experimentally measured, but rather assumed or fit to the data; and (4) the target ligand dissociation rate and hydride association rate have not been determined in this complex in the published literature. The hydride association rate (k_{a,H}) was fixed at 0.2 s⁻¹ because the impact of this rate on the fine structure of the plots is minimal. The ligand dissociation rate was fit to the data (k_{d,N}). All parameters used in the simulations were either defined (²J_{H-H′}=−10 Hz, k_{a,H}=0.2 s⁻¹), set to the experimental values (magnetic field sequence, relative concentrations of ligand and catalyst), or varied to fit the experimental data (³J_{C-II}, k_{d,N}). The experimental results presented in FIGS. 4-6 were simulated and the ³J_{C-H} and k_{d,N} values were determined by minimization of the RMSD between the experimental and numerical results.

In one example, the experimental apparatus was used to investigate the effect of application of combination of alternating and static microtesla magnetic fields on [1-¹³C]pyruvate complexes. Starting with a zero-field, high-field pulse sequence, varying the duration of the high-field pulse, τ_{HIGH}, resulted in oscillatory behavior. The polarization periodically shows sharp resonance conditions centered at specific rotations about the resonance frequency difference, Δω_{CH}, between Î₁ and Ŝ. The polarization transfer minima and maxima are centered about pulse durations τ_{HIGH} that induce an angular rotation θ_{HIGH}=2·π·n, which occurs under pulse conditions that satisfy θ_{HIGH}=τ_{HIGH}·(ω_{H}−ω_{C})=2·π·B_{HIGH}. τ_{HIGH}. (γ_{H}−γ_{C})=2·T·n. θ_{HIGH} corresponds to the angular separation between the Î₁ and Ŝ vectors due to the resonance frequency difference between the carbon-13 and hydride nuclei in the applied field. The transverse components of these vectors will rotate relative to one another at the difference between the precession frequencies of the two nuclei. Over a certain time period t, this angular difference θ_{HIGH} would then be equal to the frequency difference multiplied by the duration that this rotation is occurring: θ_{HIGH}=2π(ω_{H}−ω_{C})τ_{HIGH}=2πB_{HIGH}τ_{HIGH} (γ_{H}−γ_{C}). The extra 2π coefficient is present to ensure the angle is in radians for clarity. This angle is useful in understanding the action of the pulse sequence. Rather non-intuitively, the benefit of the pulsed SABRE-SHEATH sequences would come from attenuation of the J coupling between the hydrides and the target nucleus (e.g., ³J_{C-H} in the case of [1-¹³C]pyruvate shown in FIG. 3). The J coupling drives oscillation of population between the initialized state with singlet spin order on parahydrogen-derived hydrides and a target state with magnetization on the target nucleus. With a large J coupling, this oscillates rapidly and some of the spin order can be returned to the initial state by “back-pumping”before the ligand exchanges at a rate k_{d,L}. Reduction of this coupling allows for efficient population transfer into the target state with a reduction of this “back-pumping” effect. For a spin system like the dominant polarization transfer complexes in [1-¹³C]pyruvate solutions, the assumed 3J_{C-H} is already small (˜5 Hz) and on the order of the exchange rate calculated for this complex, so further effective attenuation of this coupling does not result in meaningful improvements in the polarization transfer.

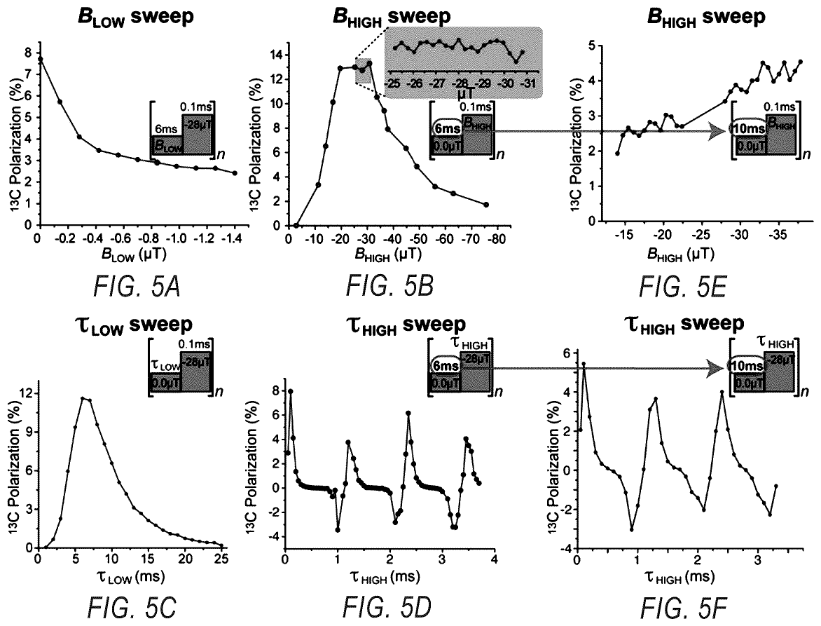

In one example, the optimal τ_{HIGH} from this sweep corresponds to the condition where the time weighted average of the applied field is equivalent to the optimal continuous field condition. Additional sweeps through the other three parameters in the pulse sequence (B_{HIGH}, B_{LOW}, and τ_{LOW}) shown in FIGS. 4B, 4C, and 4D bear this out. Each parameter is optimized at the condition where the effective field over the course of the pulse sequence is equal to the continuous field optimum. This behavior is in good agreement with numerical simulations shown by the solid red lines overlaying the experimental data (shown by circles in FIGS. 4A-4D). It is noted that if the experiment is performed using different parameters (e.g., “off-resonance conditions”), the observed trends may look substantially different. For example, if the B_{HIGH} Sweep is performed with τ_{LOW}=10 ms (versus 6 ms), the P_{13C} maximum is no longer located in the range of 12-22 μT, FIGS. 5E and 5B, respectively. Moreover, a τ_{HIGH} sweep performed with τ_{LOW}=10 ms, FIG. 5F (versus 6 ms, FIG. 5D) exhibits “spikes” that resemble sinusoidal periodicity, yet the maxima positions remain the same, FIGS. 5F, 5D and FIG. 6.

In one example, the optimal pulsed field conditions are found at τ_{LOW}=6 ms, B_{LOW}=0 μT, τ_{HIGH}=96 μs, and B_{HIGH}=−28 μT. Under these conditions, the P_{13C} build-up rate and final polarization is equivalent to the optimal continuous field experiment (control experiment) at B=−0.42 μT as seen in FIG. 4A. Furthermore, and perhaps more surprisingly, FIG. 7B shows that the polarization decay after hyperpolarization is also identical when the sample is exposed to these field conditions. For these experiments, once P_{13C} was fully established in our sample, the p-H₂ flow was stopped, the sample was allowed to depolarize at the field of interest, and P_{13C} was then checked using a 1.4 T NMR spectrometer. Systematic mapping of this process allows measuring effective ¹³C polarization decay rates at arbitrary fields of interest. These mono-exponential decay constants in FIG. 7C were measured for fields ranging from 0.21 μT down to 0 μT, showing a sharp decrease as the field approaches 0 μT: 1.9+0.9 s (at 0.00±0.04 μT), 5.8=0.9 s (at −0.06 μT), 9.6±0.7 s (at −0.11 μT), and 20.7±0.3 s (at −0.21 μT). Simulations were also performed using a model of a normal distribution for the field inhomogeneity centered about some average field (5 nT, 10 nT, 20 nT, 40 nT, 80 nT and 160 nT, FIG. 7E) with a standard deviation that is equal to half the average field. This simplistic model clearly shows that as the residual B_{x-y} field increases, Ta decreases even at relatively high B_{z} values of 0.42 μT, FIG. 7E. Qualitative inspection of these simulated trends with experimental data (see trace 702 of FIG. 7E), and quantitative RMSD analysis (see FIG. 7F) reveal the magnitude of residual B_{x-y} field of approximately 80 nT. This value is in overall good agreement with estimated residual field of 40 nT (in each direction, i.e., Bₓ and B_{y}) combined with the precision of our measurement device. The polarization decay was also measured at the Earth's field to approximate the behavior under B_{HIGH}, and at the measurement field, 1.4 T in FIG. 7D. These decay constants −26.4±1.2 s and 79.3±1.9 s, respectively—were “predictably” longer than the corresponding near-zero measurements. As the relaxation rate is dependent on the correlation time for a specific molecule (on the order of picoseconds), the instantaneous field in the proposed sequence will govern the relaxation dynamics. One would therefore expect that the polarization decay rate for the pulsed field experiments, which stays at 0 μT for ˜98% of the total field sequence duration, would be similar to the decay rate for the 0 μT static field. However, a marked decrease was seen in the polarization decay for the static 0 μT field condition. These dramatic changes in apparent relaxation dynamics at near zero field should not be mistakenly taken for ¹³C T1 decrease because the spin system of interest does not experience any new energy level crossing that may potentially result in additional sources of spin relaxation. Instead, these observations are rationalized through the existence of weak residual magnetic fields in the x-y plane (arising from the Earth and/or magnetization of the shield), which are orthogonal to the B₀ field supplied by the solenoid magnet along the z-axis, FIG. 1D. As a result, ¹³C polarization rapidly dephases at an ever-increasing pace as the B₀ decreases in the experiment, shown in FIG. 7C, resulting in a ¹³C effective depolarization constant, Td, that becomes progressively smaller compared to T1 (as measured at B_{z} of −0.42 μT or at the Earth's magnetic field (ca. 50 μT), as B_{z} approaches 0 μT. On the other hand, during a pulsed experiment, the sample experiences near-zero field dephasing for a negligible period of time compared to 1/ω0. For example, at 0.04 μT residual x-y field, 1/ω0 is ˜2 s, which is vastly greater than the 6 ms duration employed in FIG. 7A. In other words, the ¹³C spins dephase by less than 1° during 6 ms at a 0.04 μT dephasing field (estimated by dividing the Earth's magnetic field value of ca. 50 μT by the shield attenuation factor of ˜1,200). Next, the short application of the −28 μT pulse effectively recovers the dephasing effects of the near-zero x-y residual magnetic fields, because during 96 μs (e.g., see FIG. 7A), the ¹³C spin can cover >100°, which is vastly greater than dephasing by 1°. This spin-system behavior becomes possible because τ_{LOW}/(1/ω0) or τ_{LOW}*ω0 is substantially lower at B_{LOW} compared B_{HIGH}. The limitation of such experimental setups (including the one employed for this example) operating at static magnetic fields (especially for measurements of polarization build-up and decay at B_{z} approaching 0 μT) can be potentially improved through the implementation of x-y coils and the application of alternating (+x)−(+y)−(−x)−(−y) pulses to decouple the dephasing effects of residual x-y magnetic fields in the shields.

In one example, the approach employing the combination of alternating and static microtesla magnetic fields yield overall similar (within experimental error) build-up and relaxation decay rates in the microtesla regime as the control experiment (employing only static microtesla field), FIG. 7A. The gain in observed ¹³C polarization (14.8% in this report, FIG. 1B) versus ˜12% in [1-¹³C]pyruvate is primarily the result of the use of the overall higher p-H₂ pressure and flow rates: 120 sccm at 9.2 atm versus 70 sccm and 8 atm, respectively. These observations suggest that P_{13C} on [1-¹³C]pyruvate can be further additionally improved through the use of high-pressure and high-flow experimental setups.

Other embodiments are envisioned where more robust and efficient combinations of alternating and static microtesla magnetic fields may be possible to further boost [1-¹³C]pyruvate polarization efficiency by minimizing the sample exposure to near-zero magnetic fields to reduce the contribution from unfavorable relaxation. From the substrate perspective, the presented approach may be applied to other bio-α-ketocarboxylates including [1-¹³C]α-ketoglutarate and [1-¹³C]α-ketoisocaproate.

In one example, the techniques discussed herein were used to efficiently hyperpolarize ¹³C nucleus to yield P_{13C} of nearly 15% at the time of detection. The P_{13C} of the approach employing the combination of alternating and static microtesla magnetic fields matches that of the static SABRE-SHEATH performed at the optimum field of −0.42 μT despite vastly unfavorable P_{13C} dephasing dynamics at the near-zero magnetic field, where the spin system spends most of its time during the pulsed experiment. In the context of biomedical translation, the presented results were obtained at a relatively high [1-¹³C]pyruvate concentration of 27 mM in 0.6 mL volume, which would provide a sufficient bolus for future pilot in vivo applications of HP [1-¹³C]pyruvate produced via SABRE-SHEATH in small rodents.

While the preceding discussion is generally provided in the context of medical imaging application of injectable hyperpolarized [1-¹³C]pyruvate contrast agent, it should be appreciated that the present techniques are not limited to such medical contexts. The provision of examples and explanations in such a medical context is to facilitate explanation by providing instances of implementations and applications. The disclosed approaches may also be utilized in other contexts, such as the non-destructive inspection of manufactured parts or goods (i.e., quality control or quality review applications), and/or the non-invasive inspection or imaging techniques.

While the disclosed materials have been described in detail in connection with only a limited number of embodiments, it should be readily understood that the embodiments are not limited to such disclosed embodiments. Rather, that disclosed can be modified to incorporate any number of variations, alterations, substitutions or equivalent arrangements not heretofore described, but which are commensurate with the spirit and scope of the disclosed materials. Additionally, while various embodiments have been described, it is to be understood that disclosed aspects may include only some of the described embodiments. Accordingly, that disclosed is not to be seen as limited by the foregoing description, but is only limited by the scope of the appended claims.

With further regard to FIGS. 1-10 and the examples, processes, systems, methods, techniques, heuristics, and etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain examples, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description or Abstract below, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary. Further, the use of terms such as “first,” “second,” “third,” and the like that immediately precede an element(s) do not necessarily indicate sequence unless set forth otherwise, either explicitly or inferred through context.

While the disclosed materials have been described in detail in connection with only a limited number of embodiments, it should be readily understood that the embodiments are not limited to such disclosed embodiments. Rather, that disclosed can be modified to incorporate any number of variations, alterations, substitutions or equivalent arrangements not heretofore described, but which are commensurate with the spirit and scope of the disclosed materials. Additionally, while various embodiments have been described, it is to be understood that disclosed aspects may include only some of the described embodiments. As such, that disclosed is not to be seen as limited by the foregoing description, but is only limited by the scope of the appended claims.

1. A hyperpolarization system comprising:
a solution comprising at least parahydrogen, a polarization transfer complex (PTC), and substrate molecules;
at least one magnetic field controller, the least one magnetic field controller configured to:
apply a static ultra-low magnetic field to the solution; and
apply an alternating ultra-low magnetic field to the solution, wherein the system is configured to hyperpolarize at least some of the substrate molecules after the static magnetic field and alternating magnetic field are applied, wherein the ultra-low magnetic fields are each in a range from 0.001 microtesla to 39,999 microtesla.

2. The hyperpolarization system of claim 1, wherein application of the static ultra-low magnetic field and the alternating ultra-low magnetic field occurs at substantially the same time.

3. The hyperpolarization system of claim 2, wherein at least one of the static ultra-low magnetic field and the alternating ultra-low magnetic field is variable.

4. The hyperpolarization system of claim 1, wherein the substrate molecules include [1-¹³C]pyruvate molecules, and wherein the static ultra-low magnetic field and the alternating ultra-low magnetic field are each in a microtesla range.

5. The hyperpolarization system of claim 4, wherein the substrate molecules further include dimethyl sulfoxide (DSMO) molecules, and wherein the hyperpolarization of at least some of the substrate molecules includes hyperpolarization of the [1-¹³C]pyruvate molecules.

6. The hyperpolarization system of claim 4, wherein the least one magnetic field controller is further configured to apply the static ultra-low magnetic field parallel to the alternating ultra-low magnetic field.

7. The hyperpolarization system of claim 4, wherein the controller is further configured to apply the static ultra-low magnetic field orthogonal to the alternating ultra-low magnetic field.

8. The hyperpolarization system of claim 4, wherein the static ultra-low magnetic field has from one to three spatial directions or components.

9. The hyperpolarization system of claim 4, wherein the PTC is formed via a pre-catalyst, and wherein the pre-catalyst includes (IrCl(COD)(IMes).

10. A method hyperpolarizing a substrate, the method comprising:
creating a solution including parahydrogen, a polarization transfer complex (PTC), and substrate molecules;
applying a static ultra-low magnetic field to the solution; and
applying an alternating ultra-low magnetic field to the solution, wherein applying the static ultra-low magnetic field and the alternating ultra-low magnetic field induces hyperpolarization of at least some of the substrate molecules, and wherein the static ultra-low magnetic field and the alternating ultra-low magnetic fields each fall in a range from 0.001 microtesla to 39,999 microtesla.

11. The method of claim 10 further comprising creating the PTC via a pre-catalyst, wherein interaction of the parahydrogen with the pre-catalyst creates the PTC.

12. The method of claim 11, wherein the static ultra-low magnetic field and the alternating ultra-low magnetic field are in a range from 0.001 microtesla to 999 microtesla, and wherein the pre-catalyst includes (IrCl(COD)(IMes).

13. The method of claim 10, wherein the substrate molecules include [1-³C]pyruvate molecules.

14. The method of claim 13, wherein the substrate molecules further include dimethyl sulfoxide (DSMO) molecules, and wherein the hyperpolarization of at least some of the substrate molecules includes hyperpolarization of the [1-¹³C]pyruvate molecules.

15. The method of claim 10, wherein applying the alternating ultra-low magnetic field includes applying the alternating ultra-low magnetic field parallel to the static ultra-low magnetic field.

16. The method of claim 10, wherein applying the alternating ultra-low field includes applying the alternating ultra-low magnetic field orthogonal to the static ultra-low magnetic field.

17. The method of claim 10, wherein the static ultra-low magnetic field has from one to three spatial directions or components.

18. The method of claim 10, wherein the applying the alternating ultra-low magnetic field includes applying the alternating ultra-low magnetic field at a substantially same time as applying the static ultra-low magnetic field.

19. The method of claim 10, wherein amplitude and phase of the static ultra-low magnetic field are variable.

20. The method of claim 15, wherein amplitude and phase of the alternating ultra-low magnetic field are variable.
